(19) United States
(12) Patent Application Publication
(10) Pub. No.: US 2023/0026807 A1
(43) Pub. Date: Jan. 26, 2023

(54) SEMICONDUCTOR MANUFACTURING APPARATUS, CONDITION COMPENSATION METHOD, AND PROGRAM

(71) Applicant: Tokyo Electron Limited, Tokyo (JP)

(72) Inventor: Toshiharu HIRATA, Yamanashi (JP)

(21) Appl. No.: 17/862,889

(22) Filed: Jul. 12, 2022

(30) Foreign Application Priority Data
Jul. 20, 2021 (JP) 2021-119340

(51) Int. Cl. H01J 37/34; C23C 14/34; C23C 14/54

(52) U.S. Cl. CPC H01J 37/3479; C23C 14/34; C23C 14/54; H01J 2237/332

(57) ABSTRACT

A semiconductor manufacturing apparatus for forming a film on a substrate by sputtering a target based on a recipe for performing film formation is provided. The apparatus comprises: a storage device configured to store an adjustment coefficient for adjusting a film quality of the formed film based on the recipe; a monitoring device configured to monitor a used amount of the target; a compensation device configured to calculate a compensation value for compensating at least one of process conditions set in the recipe by inputting the used amount of the target monitored by the monitoring device and the adjustment coefficient into a calculation formula; and a recipe execution device configured to execute film formation based on the recipe and the compensation value.

### CROSS-REFERENCE TO RELATED APPLICATIONS

This application claims priority to Japanese Patent Application No. 2021-119340 filed on Jul. 20, 2021, the entire contents of which are incorporated herein by reference.

### TECHNICAL FIELD

The present disclosure relates to a semiconductor manufacturing apparatus, a condition compensation method, and a program.

### BACKGROUND

When a semiconductor manufacturing apparatus forms a film on a substrate such as a wafer or the like, a recipe is created by making various settings on a recipe screen so that a desired film thickness (or refractive index) can be obtained. The optimal values of process conditions of the semiconductor manufacturing apparatus are set in the recipe. However, it is known that the optimization of the recipe has a heavy workload. Further, in the case of mass production, it may not be easy to change the recipe in view of the recipe management.

For example, a technique for supporting optimization of output values of a plurality of plasma sources is known (see, e.g., Japanese Laid-open Patent Publication No. 2021-72422). Japanese Laid-open Patent Publication No. 2021-72422 discloses an information processing device that stores a film thickness model that defines the amount of change in a film thickness at each position of a first wafer when film formation is performed by changing the output of each plasma source of a semiconductor manufacturing apparatus having a plurality of plasma sources by a predetermined amount, and calculates a compensation value of the output of each plasma source for achieving a target value of the film thickness at each position of a second wafer based on the film thickness model.

### SUMMARY

The present disclosure provides a technique for optimizing film formation in response to the used amount of a sputtering target.

Specifically, the present disclosure provides a semiconductor manufacturing apparatus for forming a film on a substrate by sputtering a target based on a recipe for performing film formation, comprising: a storage device configured to store an adjustment coefficient for adjusting a film quality of the formed film based on the recipe; a monitoring device configured to monitor a used amount of the target; a compensation device configured to calculate a compensation value for compensating at least one of process conditions set in the recipe by inputting the used amount of the target monitored by the monitoring device and the adjustment coefficient into a calculation formula; and a recipe execution device configured to execute film formation based on the recipe and the compensation value.

### BRIEF DESCRIPTION OF THE DRAWINGS

The objects and features of the present disclosure will become apparent from the following description of embodiments, given in conjunction with the accompanying drawings, in which:

FIG. 1 is a schematic cross-sectional view showing an example of a semiconductor manufacturing apparatus;

FIG. 2 is a schematic cross-sectional view showing an example of a wafer transfer path of the semiconductor manufacturing apparatus;

FIG. 3 is a schematic cross-sectional view showing an example of a substrate processing apparatus of the semiconductor manufacturing apparatus;

FIG. 4 is a configuration diagram of an example of a controller;

FIG. 5 shows an example of a recipe in the case where the semiconductor manufacturing apparatus performs film formation by PVD;

FIG. 6 is a functional block diagram of an example of the controller;

FIG. 7 shows examples of adjustment coefficients stored in an adjustment coefficient storage device;

FIG. 8 is an example of a flowchart illustrating a process in which the controller calculates a compensation value of a film formation time;

FIG. 9 shows an example of a recipe screen displayed by the controller;

FIG. 10 is an example of a flowchart illustrating a process in which the controller calculates a compensation value of an input power to a plasma generation power source;

FIG. 11 shows an example of a recipe screen displayed by the controller;

FIG. 12 is an example of a flowchart illustrating a process in which the controller calculates a compensation value of an input power to a plasma generation power source; and

FIG. 13 shows an example of a recipe screen displayed by the controller.

### DETAILED DESCRIPTION

Hereinafter, non-limiting exemplary embodiments of the present disclosure will be described with reference to the accompanying drawings. Like reference numerals will be given to like or corresponding parts or components throughout the drawings, and redundant description thereof will be omitted.

(Supplement Process of Film Formation by PVD)

When a semiconductor manufacturing apparatus forms a film on a substrate such as a wafer or the like by physical vapor deposition (PVD), a material referred to as a target is sputtered, and sputtered particles (atoms, molecules or ions) released from the target by an ionic impact are deposited onto the substrate, thereby forming a film on the substrate.

In order to obtain a desired film thickness in this film forming process, a user inputs, on a recipe screen, a film forming rate and a film thickness required in one step in advance under sputtering conditions such as an input power to a plasma generation power source, a gas pressure, and the like. The controller for controlling the semiconductor manufacturing apparatus calculates a film formation time from the film forming rate and the film thickness and applies the calculated film formation time to the recipe. The semiconductor manufacturing apparatus performs film formation for the film formation time calculated based on the recipe. In order to obtain satisfactory film thickness distribution on the substrate, the controller performs film formation while automatically adjusting the position or angle of the target.

The process conditions such as the film formation time, the input power, the position or angle of the target, and the like, which are inputted to the controllers, are optimized depending on the film formation performed as preliminary preparation of wafer production and an inspection result thereof.

However, it was found that the optimal values of the process conditions are different between when the use of the target is started and when the used amount of the target has increased.

In other words, even when a film is formed based on the same recipe, the film quality (film thickness, uniformity of film thickness, refractive index of film, or the like) is different between when the use of the target is started and when the use of the target has reached the limit. This is because the surface shape of the target is different between when the use of the target is started and when the use of the target has reached the limit, and directions or strengths of sputtered particles released from the target is also changed.

On the other hand, it may be difficult to change the recipe set before the start of the production after the start of the production because it requires re-optimization of the film formation conditions or because it is not easy in view of recipe management.

Therefore, in the present disclosure, even when the used amount of the target has increased compared to when the use of the target is started (i.e., when the optimization is completed), it is possible to maintain the film quality or at least suppress deterioration of the film quality by causing the controller to perform the following three compensation processes.

1. The controller calculates the compensation value of the film formation time in response to the used amount of the target.

2. The controller calculates the compensation value of the input power in response to the used amount of the target.

3. The controller calculates the compensation value of the distance (hereinafter, referred to as “TS distance”) between the target and the substrate support in response to the used amount of the target.

### Embodiment 1

In the present embodiment, the controller that performs “1. calculation of the compensation value of the film formation time in response to the used amount of the target” will be described.

(Semiconductor Manufacturing Apparatus)

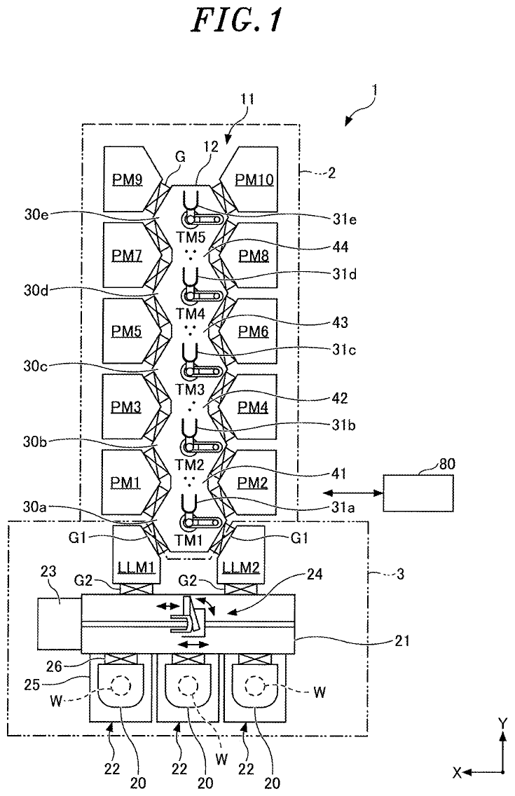

First, a semiconductor manufacturing apparatus 1 capable of forming a film by PVD will be described with reference to FIG. 1. FIG. 1 is a schematic cross-sectional view showing an example of the semiconductor manufacturing apparatus 1 according to the present embodiment. The semiconductor manufacturing apparatus 1 performs multiple processes (desired processes such as etching, film formation, ashing, and the like) on the substrate W. The semiconductor manufacturing apparatus 1 includes a processor 2, a loading/unloading device 3, and a controller 80. The substrate W is not particularly limited, but is a semiconductor wafer (hereinafter, simply referred to as “wafer”), for example.

The loading/unloading device 3 loads and unloads the substrate, e.g., a wafer, into and from the processor 2. The processor 2 includes a plurality of (ten in the present embodiment) process modules PM1 to PM10 for performing desired vacuum processing on the wafer. A first transfer device 11 serially transfers (sequentially transfers) wafers to the plurality of process modules PM1 to PM10.

The first transfer device 11 includes a plurality of transfer modules TM1 to TM5. The transfer modules TM1 to TM5 have containers 30a, 30b, 30c, 30d and 30e held in a vacuum state and having a hexagonal planar shape, respectively. Further, the transfer modules TM1 to TM5 have transfer mechanisms 31a, 31b, 31c, 31d and 31e having an articulated structure in the containers 30a, 30b, 30c, 30d and 30e, respectively.

Delivery devices 41, 42, 43 and 44 as transfer buffers are disposed between the transfer mechanisms 31a, 31b, 31c, 31d and 31e of the transfer modules TM1 to TM5, respectively. The containers 30a, 30b, 30c, 30d and 30e of the transfer modules TM1 to TM5 communicate with each other to form one transfer chamber 12.

The transfer chamber 12 extends in the Y direction in the drawings. Among the process modules PM1 to PM10, five process modules are connected to each side of the transfer chamber 12 through openable and closeable gate valves G. The gate valves G of the process modules PM1 to PM10 are opened when the transfer modules TM1 to TM5 access the process modules PM1 to PM10, and are closed while a desired process is being performed.

The loading/unloading device 3 is connected to one end side of the processor 2. The loading/unloading device 3 includes an atmospheric transfer chamber 21, three load ports 22, an aligner module 23, two load-lock modules LLM1 and LLM2, and a second transfer device 24. The load port 22, the aligner module 23, and the load-lock modules LLM1 and LLM2 are connected to the atmosphere transfer chamber 21. Further, the second transfer device 24 is disposed in the atmospheric transfer chamber 21.

The atmosphere transfer chamber 21 has a rectangular parallelepiped shape with the X direction as a longitudinal direction in the drawings. The three load ports 22 are disposed on a long wall of the atmospheric transfer chamber 21 opposite to a long wall facing the processor 2. Each of the load ports 22 has a FOUP 25 and a transfer port 26. The FOUP 20 that is a substrate container accommodating a plurality of wafers is placed on a FOUP table 25. The FOUP 20 on the FOUP table 25 is connected in a sealed state to the atmospheric transfer chamber 21 through the transfer port 26. The aligner module 23 is connected to one short wall of the atmospheric transfer chamber 21. The wafer is aligned in the aligner module 23.

The pressure in each of the two load-lock modules LLM1 and LLM2 for transferring a wafer between the atmospheric transfer chamber 21 having an atmospheric pressure and the transfer chamber 12 having a vacuum atmosphere can be switched between the atmospheric pressure and the vacuum that is substantially the same as that in the transfer chamber 12. Each of the two load-lock modules LLM1 and LLM2 has two transfer ports. One is connected to the long wall of the atmosphere transfer chamber 21 facing the processor 2 through a gate valve G2. The other is connected to the transfer chamber 12 of the processor 2 through a gate valve G1.

The load-lock module LLM1 is used for transferring a wafer from the loading/unloading device 3 to the processor 2. The load-lock module LLM2 is used for transferring a wafer from the processor 2 to the loading/unloading device 3. The load-lock modules LLM1 and LLM2 may be used for processing such as degassing or the like.

The second transfer device 24 in the atmospheric transfer chamber 21 has an articulated structure and transfers a wafer to the FOUP 20 on the load port 22, the aligner module 23, and the load-lock modules LLM1 and LLM2. Specifically, the second transfer device 24 takes out an unprocessed wafer from the FOUP 20 of the load port 22 and transfers it to the aligner module 23, and then transfers it from the aligner module 23 to the load-lock module LLM1. Further, the second transfer device 24 receives a processed wafer that has been transferred from the processor 2 to the load-lock module LLM2 and transfers it to the FOUP 20 of the load port 22. FIG. 1 shows an example in which the second transfer device 24 has one pick for receives a wafer, but the second transfer device 24 may have two picks.

The first transfer device 11 and the second transfer device 24 constitute a transfer part of the semiconductor manufacturing apparatus 1. In the processor 2, the process modules PM1, PM3, PM5, PM7 and PM9 are arranged on one side of the transfer chamber 12 in that order from the load-lock module LLM1 side. Further, in the processor 2, the process modules PM2, PM4, PM6, PM8 and PM10 are arranged on the other side of the transfer chamber 12 in that order from the load-lock module LLM2 side. In the first transfer device 11, the transfer modules TM1, TM2, TM3, TM4 and TM5 are arranged in that order from the load-lock modules LLM1 and LLM2 side.

The transfer mechanism 31a of the transfer module TM1 can access the load-lock modules LLM1 and LLM2, the process modules PM1 and PM2, and the delivery device 41. The transfer mechanism 31b of the transfer module TM2 can access the process modules PM1, PM2, PM3 and PM4, and the delivery devices 41 and 42.

The transfer mechanism 31c of the transfer module TM3 can access the process modules PM3, PM4, PM5 and PM6, and the delivery devices 42 and 43. The transfer mechanism 31d of the transfer module TM4 can access the process modules PM5, PM6, PM7 and PM8, and the delivery devices 43 and 44. The transfer mechanism 31e of the transfer module TM5 can access the process modules PM7, PM8, PM9 and PM10, and the delivery device 44.

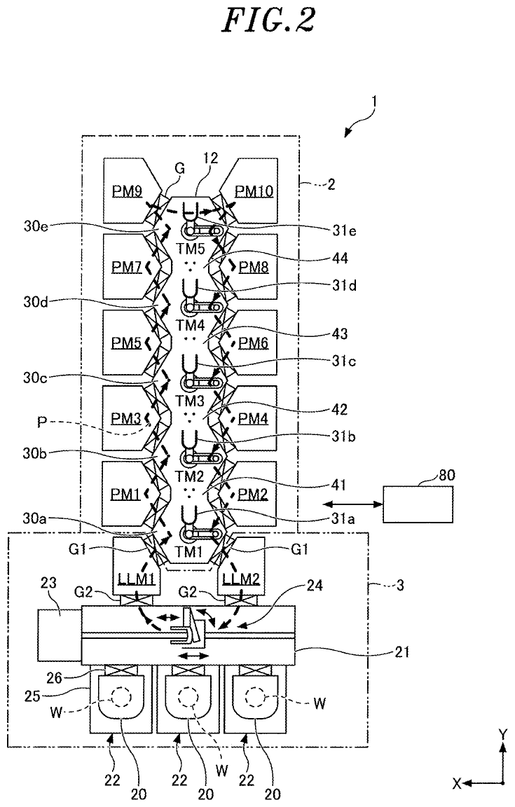

The transfer modules TM1 to TM5 of the second transfer device 24 and the first transfer device 11 are configured as shown in FIG. 1. Therefore, as shown in FIG. 2, the wafer taken out from the FOUP 20 is serially transferred in one direction along a substantially U-shaped path P in the processor 2, processed by the process modules PM1 to PM10, and returned to the FOUP 20. In other words, the wafer is serially transferred in the order of the process modules PM1, PM3, PM5, PM7, PM9, PM10, PM8, PM6, PM4, and PM2 and subjected to desired processing.

The semiconductor manufacturing apparatus 1 can be used for manufacturing a magnetoresistive tunnel junction (MTJ) film used for a magnetoresistive random access memory (MRAM), for example. The MTJ film is manufactured by performing a plurality of desired processes such as pre-cleaning, film formation, oxidation, heating, cooling, and the like. Each of the desired processes is performed in the process modules PM1 to PM10. One or more of the process modules PM1 to PM10 may be standby modules where a wafer stands by.

The controller 80 controls individual components of the semiconductor manufacturing apparatus 1. The controller 80 controls, e.g., the transfer modules TM1 to TM5 (transfer mechanisms 31a to 31e), the second transfer device 24, the process modules PM1 to PM10, the load-lock modules LLM1 and LLM2, the transfer chamber 12, and the gate valves G, G1 and G2. The controller 80 is, e.g., a computer.

<Substrate Processing Apparatus>

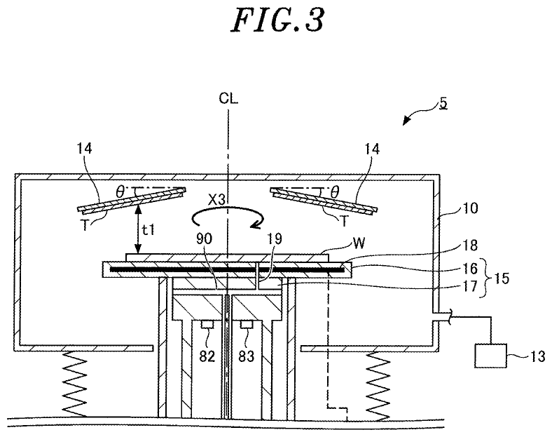

Next, a substrate processing apparatus 5 used in any of the process modules PM1 to PM10 will be described. FIG. 3 is a schematic cross-sectional view of the substrate processing apparatus 5 of the semiconductor manufacturing apparatus 1 according to the present embodiment.

The substrate processing apparatus 5 performs desired film formation on a substrate W such as a semiconductor wafer that is a substrate to be processed in a vacuum processing chamber 10 where a vacuum atmosphere is formed and a substrate is processed by a processing gas. The substrate processing apparatus is a PVD apparatus.

The substrate processing apparatus 5 includes the vacuum processing chamber 10, a substrate support 15, and the like. The substrate support 15 places thereon the substrate W in the vacuum processing chamber 10.

The substrate support 15 is disposed at an inner lower portion of the vacuum processing chamber 10, and a plurality of target holders 14 are disposed above the substrate support 15 and fixed at a predetermined inclination angle θ with respect to a horizontal plane. Different types of targets T are attached to the bottom surfaces of the target holders 14. The inclination angle θ is 0°. In other words, the target holders 14 may be fixed horizontally.

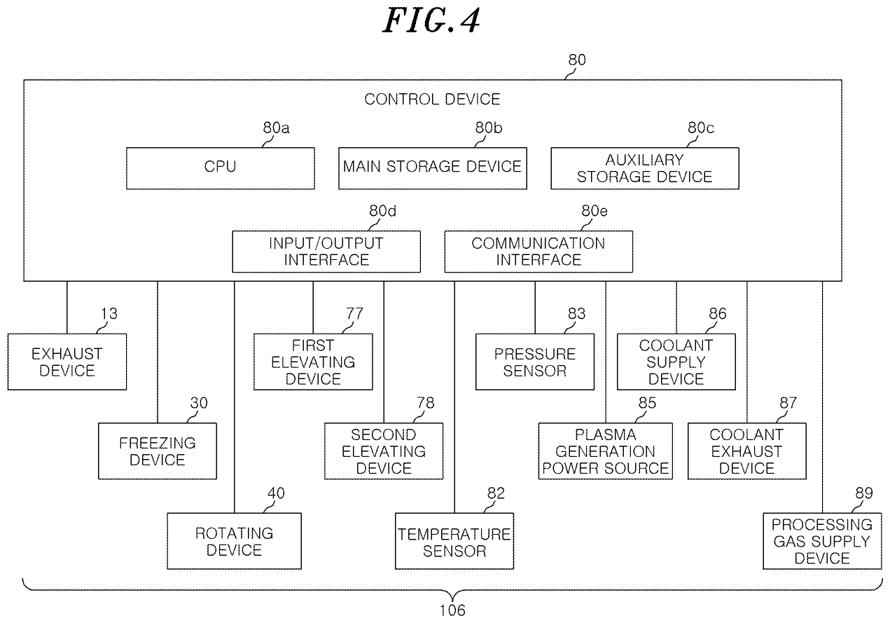

The vacuum processing chamber 10 is configured such that a pressure therein is decreased to vacuum by operating an exhaust device 13 such as a vacuum pump or the like. A processing gas (e.g., noble gas such as argon (Ar), krypton (Kr), neon (Ne), or the like, or nitrogen (N₂) gas) required for sputtering film formation is supplied from a processing gas supply device 89 (see FIG. 4) to the vacuum processing chamber 10.

An AC voltage or DC voltage is applied from a plasma generation power source 85 (see FIG. 4) to the target holders 14. When an AC voltage is applied from the plasma generation power source 85 to the target holders 14 and the targets T, plasma is generated in the vacuum processing chamber 10, and the noble gas or the like in the vacuum processing chamber 10 is ionized. Then, the targets T are sputtered by ionized noble gas elements or the like. Accordingly, the sputtered particles released from the targets T are deposited on the surface of the substrate W held on the substrate support 15 while facing the targets T.

Since the targets T are inclined with respect to the substrate W, a user can adjust an incident angle at which the sputtered particles sputtered from the targets T are incident on the substrate W, and the in-plane uniformity of the film thickness of a magnetic film or the like formed on the substrate W can be improved. Even when the target holders 14 are arranged at the same inclination angle θ in the vacuum processing chamber 10, it is possible to change a distance t1 between the targets T and the substrate W by raising and lowering the substrate support 15, and also possible to change the incident angle of the sputtered particles with respect to the substrate W. Therefore, the substrate support 15 can be raised and lowered such that the distance t1 becomes suitable for each target T.

Although the number of targets T is not particularly limited, it is preferable to provide a plurality of different types of targets T in the vacuum processing chamber 10 in order to sequentially form different types of films made of different materials by one substrate processing apparatus 5.

In addition, the substrate processing apparatus 5 includes a freezing device, a rotating device, an elevating device, and the like. The freezing device cools the substrate support 15 or heats the substrate support 15 by driving a freezing cycle in a reverse cycle. The rotating device rotates the substrate support 15 in order to obtain the uniformity of the film thickness. The elevating device can adjust the distance t1 (TS distance) between the targets T and the substrate W by raising and lowering the substrate support 15 in the vacuum processing chamber 10. The adjustment of the distance t1 is appropriately changed depending on types of the targets T to be applied. The description of the freezing device, the rotating device, and the elevating device, which are not characteristics of the present embodiment, will be omitted.

### Configuration Example of Controller

FIG. 4 shows a configuration diagram of an example of the controller 80. The controller 80 has a function of a computer, a microcomputer, or an information processor. The controller 80 includes a central processing unit (CPU) 80a, a main storage device 80b, an auxiliary storage device 80c, an input/output interface 80d, and a communication interface 80e, which are connected to each other by a connection bus. The main storage device 80b and the auxiliary storage device 80c are recording media that can be read by a computer. The above components may be separately provided, or some components may not be provided.

The CPU 80a is also referred to as “microprocessor (MPU) or a processor.” The CPU 80a may be a single processor or a multiprocessor. The CPU 80a is a central processing unit for controlling the entire controller 80. The CPU 80a provides a function that meets a predetermined purpose by executably developing a program stored in the auxiliary storage device 80c in a work area of the main storage device 80b and controlling peripheral devices by executing the program. The main storage device 80b stores a computer program executed by the CPU 80a, data processed by the CPU 80a, or the like. The main storage device 80b includes, e.g., a flash memory, a random access memory (RAM), or a read only memory (ROM). The auxiliary storage device 80c stores various programs and various data in a readable/writable recording medium. The auxiliary storage device 80c is also referred to as “external storage device.” The auxiliary storage device 80c stores, e.g., an operating system (OS), various programs, various tables, and the like. The OS includes a communication interface program that transmits and receives data with an external device connected through the communication interface 80e. The auxiliary storage device 80c is used as a storage area for assisting the main storage device 80b, for example, and stores a computer program executed by the CPU 80a, data processed by the CPU 80a, and the like. The auxiliary storage device 80c is a silicon disk including a non-volatile semiconductor memory (flash memory, erasable programmable ROM (EPROM)), a hard disk drive (HDD), a solid state drive device, or the like. The auxiliary storage device 80c may be, e.g., a drive device for a removable recording medium, such as a CD drive device, a DVD drive device, and a BD drive device. The removable recording medium may be a CD, a DVD, a BD, a universal serial bus (USB) memory, a secure digital (SD) memory card, or the like. The communication interface 80e is an interface for a network connected to the controller 80. The input/output interface 80d is an interface for inputting/outputting data to/from a device connected to the controller 80. The input/output interface 80d is connected to, e.g., a pointing device such as a keyboard, a touch panel, a mouse, or the like, and an input device such as a microphone or the like. The controller 80 receives an operation instruction or the like from an operator who operates the input device through the input/output interface 80d. Further, a display device such as a liquid crystal display (LCD), an organic electroluminescence (EL) panel or the like, and an output device such as a printer, a speaker, or the like are connected to the input/output interface 80d. The controller 80 outputs data and information processed by the CPU 80a, or data and information stored in the main storage device 80b and the auxiliary storage device 80c through the input/output interface 80d. A temperature sensor 82 and a pressure sensor 83 may be connected to the input/output interface 80d in a wired manner, or may be connected to the communication interface 80e through a network.

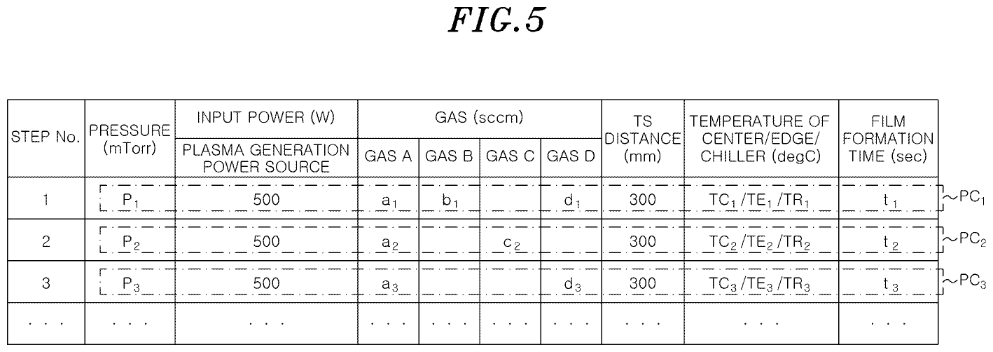

The controller 80 controls the operations of various peripheral devices 106. The peripheral devices 106 include the exhaust device 13, the freezing device 30 for cooling the substrate support 15, the rotating device 40 for rotating the substrate support 15, a first elevating device 77 for raising and lowering the substrate support 15, a second elevating device 78 for raising and lowering the freezing device 30, the temperature sensor 82, the pressure sensor 83, the plasma generation power source 85, a coolant supply device 86, a coolant exhaust device 87, the processing gas supply device 89, and the like. The CPU 80a executes a predetermined process based on the recipe stored in a storage area such as a ROM or the like. The recipe will be described with reference to FIG. 5.

The controller 80 raises and lowers the substrate support 15 (and the upper part of the freezing device 30) in the vacuum processing chamber 10 to adjust the distance t1 between the targets T and the substrate W that is suitable for a target T to be applied.

(Example of Recipe)

FIG. 5 is an example of a recipe in the case where the semiconductor manufacturing apparatus 1 forms a film by PVD. A customer side of the semiconductor manufacturing apparatus 1 prepares a recipe shown in FIG. 5 in advance, and stores the recipe data in the auxiliary storage device 80c. The CPU 80a controls the peripheral devices 106 shown in FIG. 4 based on process condition set values PCi of the recipe for each step while referring to the data of this recipe, and obtains data from the peripheral devices 106.

For example, according to the recipe of FIG. 5, in a first step, the pressure in the vacuum processing chamber 10 is set to P₁ (mTorr), the input power to the plasma generation power source 85 is set to MP1 (W), the flow rates of the film forming gases (Ar and the like) are set to a₁/b₁/d₁ (sccm), the TS distance is set to 300 (mm), the center/edge/chiller temperatures of the stage are set to TC₁/TE¹/TR¹ (degC), and the film formation time is set to t₁ (sec).

In a second and subsequent steps, the CPU 80a controls the peripheral devices 106 based on the data of each step of the recipe. In this recipe, the process condition set values PCi (pressure, input power, gas type, gas flow rate, TS distance, temperature, and film formation time) are set independently for each of the first, second, and third steps. It is often that certain process condition set values are the same in different steps.

(Function of Controller)

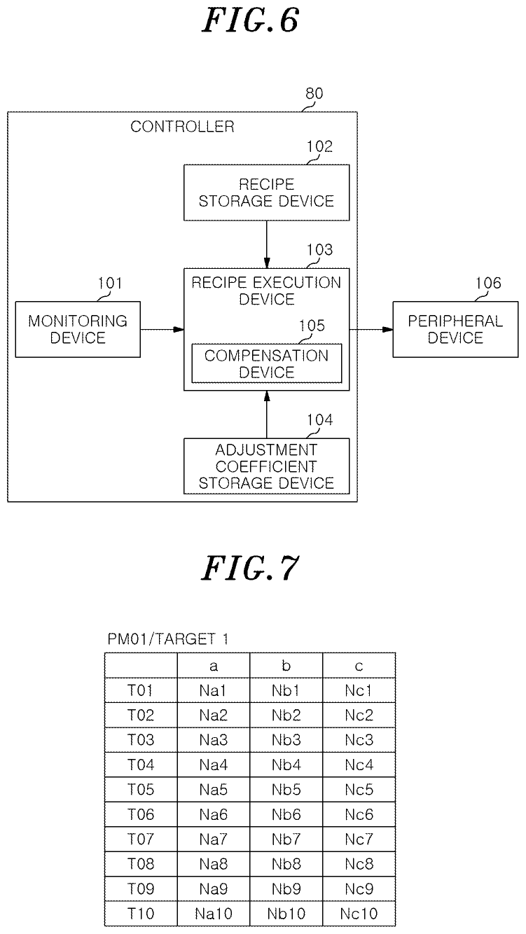

FIG. 6 shows a functional block diagram of the controller 80 for controlling the semiconductor manufacturing apparatus 1. The controller 80 includes a monitoring device 101, a recipe storage device 102, a recipe execution device 103, and an adjustment coefficient storage device 104. These functions of the controller 80 are constructed by the hardware (particularly, the CPU 80a, the main storage device 80b, the input/output interface 80d) and the software (program, algorithm, set value) of the controller 80.

The recipe execution device 103 controls the peripheral devices 106 such that the process condition set values can be obtained for each step of the recipe. The compensation device 105 of the recipe execution device 103 obtains the power consumption amount of the plasma generation power source 85 from the monitoring device 101 in order to compensate the process condition set values in response to the used amount of the target. The power consumption amount of the plasma generation power source 85 is proportional to the used amount of the target, and thus can be considered as the used amount of the target.

The monitoring device 101 monitors the input power to the plasma generation power source 85. The monitoring device 101 maintains the power consumption amount by integrating the input power used in one process while setting the power consumption amount at the time of starting the use of the target to zero. One process indicates that each step of one recipe is executed.

The recipe execution device 103 obtains the power consumption amount of the plasma generation power source 85 from the monitoring device 101 for each PJ to be described later (immediately before the start of the process). Accordingly, the recipe execution device 103 can obtain the amount of power used before the process is started.

Further, the compensation device 105 receives the process condition set values PCi from the recipe storage device 102 and the adjustment coefficients for calculating the compensation value of the film formation time from the adjustment coefficient storage device 104 for each step of the recipe. Then, the compensation device 105 calculates the compensation value of the film formation time of the recipe by inputting the adjustment coefficients and the power consumption amount to the calculation formula.

FIG. 7 shows examples of the adjustment coefficients stored in the adjustment coefficient storage device 104. The adjustment coefficient storage device 104 stores the adjustment coefficients of the film formation time as coefficients of a quadratic function with respect to the used amount of the target. In other words, the compensation device 105 calculates the compensation value of the film formation time using the calculation formula of the quadratic function such as Eq. (1), where y indicates the compensation value (sec) of the film formation time and x (variable) indicates the power consumption (W) of the plasma generation power source 85.

y=αx²+bx+c Eq. (1)

Na1 to Na10, Nb1 to Nb10, and Nc1 to Nc10 in FIG. 7 are adjustment coefficients, and correspond to the coefficients a to c in Eq. (1). The adjustment coefficients Na1 to Na10, Nb1 to Nb10, and Nc1 to Nc10 are real numbers. Since the adjustment coefficients are maintained as the coefficients of the quadratic function, the adjustment coefficients can be used for adjusting the film formation time for various targets having non-linear characteristics as well as linear characteristics, and can also be used for equalization (i.e., for eliminating differences caused by machine-to-machine variations) of the film formation. One set of the coefficients a to c is set in the row direction of FIG. 7, and one set of 10 adjustment coefficient (T01 to T10) is set in the column direction of FIG. 7. A user can register multiple adjustment coefficients, each having one set of the coefficients a to c, and can select an appropriate adjustment coefficient depending on the recipe, for example. The case where the number of adjustment coefficients is 10 is an example, and the number of adjustment coefficient may be 1 or 11 or more.

The adjustment coefficients shown in FIG. 7 are prepared for each process module PM. This is because the discharge conditions and the like vary depending on the process modules PM, and this causes machine-to-machine variations of the film formation. Further, N-number of targets can be arranged in one process module PM, so that the adjustment coefficients shown in FIG. 7 are prepared for each target. Therefore, it is preferable to prepare the adjustment coefficients for each process module PM and for each target.

When the coefficient a is 0, Eq. (1) becomes a linear equation, and it is possible to compensate the film thickness that changes in proportion to the power consumption amount. Further, the coefficient c in Eq. (1) is a fixed number, and is effective in eliminating differences caused by machine-to-machine variations or differences caused by types of targets.

As described above, the condition compensation method of the present disclosure can cope with different types of targets or different process module PMs using multiple sets of coefficients of the quadratic function as a table. Further, since the N-number of adjustment coefficients can be prepared for the combination of the process modules PM and the targets, it is possible to flexibly cope with recipes having different film thickness rates (deposition rates).

(Timing of Compensating Film Formation Time)

The processing on the wafer is executed in a control job (hereinafter, may be referred to as “CJ”) and a process job (hereinafter, may be referred to as “PJ”). CJ is a group unit of PJ set for each substrate W, and PJ is a processing unit of a recipe executed for each substrate W. PJ corresponds to one process. One or more wafers are processed in one PJ, and the maximum number of wafers are accommodated in the FOUP. Further, CJ is set for each FOUP. For example, when 25 wafers are accommodated in the FOUP, 25 wafers are processed in one CJ, and one or more wafers are processed in one PJ. The film formation time can be compensated for each PJ.

(Compensation of Film Formation Time)

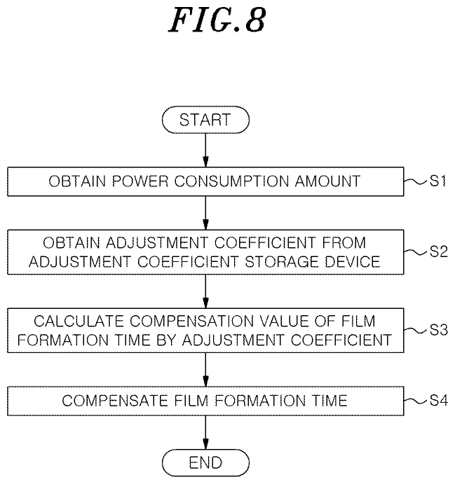

FIG. 8 is a flowchart of a condition compensation method in which the controller 80 calculates the compensation value of the film formation time. The processes of FIG. 8 are executed before one PJ is started.

First, the recipe execution device 103 obtains the power consumption amount of the plasma generation power source 85 from the monitoring device 101 (S1). The power consumption amount is a value obtained by integrating the power input to the plasma generation power source 85 from the replacement of the target.

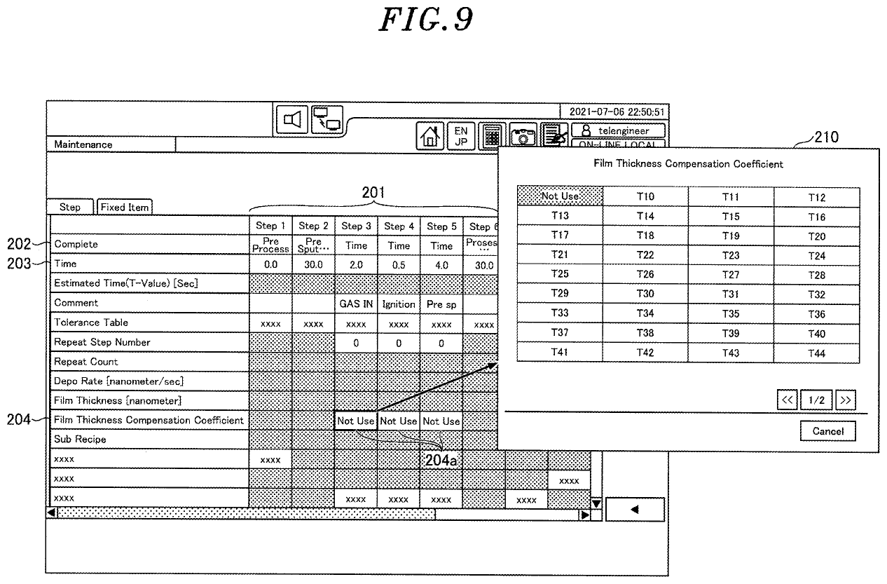

Next, the compensation device 105 obtains the adjustment coefficients a to c associated with the process module PM and the target from the adjustment coefficient storage device 104 (S2). When a plurality of adjustment coefficients are associated with the same process module PM and the same target, a user selects an adjustment coefficient to be used (see FIG. 9).

Next, the compensation device 105 calculates the compensation value of the film formation time by applying the adjustment coefficients and the power consumption amount to Eq. (1) (S3).

The recipe execution device 103 executes the recipe after the film formation time preset in the recipe is compensated for each step of the recipe (S4). For example, when the film formation time before the compensation is 5.0 (sec) and the compensation value of the film formation time is 0.3 (sec), the recipe execution device 103 performs film formation for 5.3 (sec).

(Setting of Adjustment Coefficients on Recipe Screen)

FIG. 9 shows an example of the recipe screen displayed by the controller 80. In FIG. 9, only main items will be described. In FIG. 9, an execution state 202, a film formation time (not necessarily the film formation time depending on the processing in the step) 203, and the like are displayed for each step 201 of the recipe. In addition, setting fields 204a of the film thickness compensation coefficients 204 are displayed for each step, and a user can select the film thickness compensation coefficient for each step.

As shown in FIG. 9, when the user clicks and scrolls down the setting field 204a, an adjustment coefficient selection screen 210 is displayed. As shown in FIG. 9, the user can select a desired adjustment coefficient from a list of multiple preset adjustment coefficients (although 35 coefficients are illustrated in FIG. 9, not all of them may have a set value).

<Main Effect>

In the present embodiment, a decrease in the uniformity of the film thickness due to an increase in the used amount of the target as the progress of the film formation can be suppressed by compensating the film formation time.

### Embodiment 2

In the present embodiment, the controller that performs “2. calculation of the compensation value of the input power in response to the used amount of the target” will be described.

In the present embodiment, the configuration diagrams of FIGS. 1 to 4 and the functional block diagram of FIG. 6 described in the above embodiment may be referred to.

The recipe execution device 103 of the present embodiment calculates the compensation value of the input power to the plasma generation power source 85 based on the power consumption amount of the plasma generation power source 85. Since the input power is closely related to the film thickness rate, it is possible to suppress the variation of the film thickness due to the used amount of the target by compensating the input power, similarly to the case of the film formation time. Further, when a plurality of targets are installed in one process module PM, the controller 80 cannot change the film formation time for each target, but can change the input power for each target. Therefore, it is easy to compensate different used amounts of different targets by compensating the input power.

In the present embodiment, y in Eq. (1) indicates the compensation value (W) of the input power. Since the adjustment coefficients stored in the adjustment coefficient storage device 104 may be the same as those shown in FIG. 7, the illustration thereof is omitted. The actual adjustment coefficients Na1 to Na10, Nb1 to Nb10, and Nc1 to Nc10 are values corresponding to the input power.

(Compensation of Input Power)

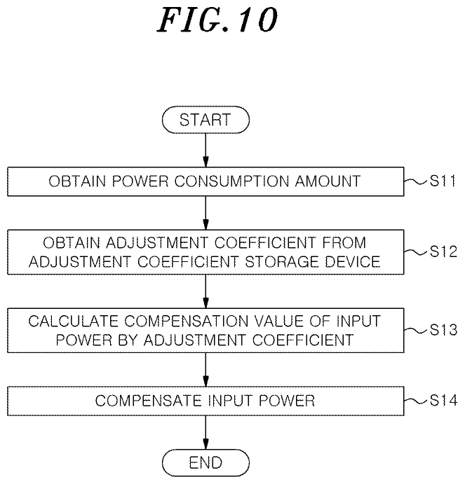

Next, the flow of the recipe compensation method in which the controller 80 compensates the conditions of the recipe will be described with reference to FIG. 10. FIG. 10 is a flowchart illustrating the condition compensation method in which the controller 80 calculates the compensation value of the input power to the plasma generation power source 85.

First, the recipe execution device 103 obtains the power consumption amount of the plasma generation power source 85 that is monitored from the monitoring device 101 (S11). The power consumption amount is a value obtained by integrating the power input to the plasma generation power source 85 from the replacement of the target.

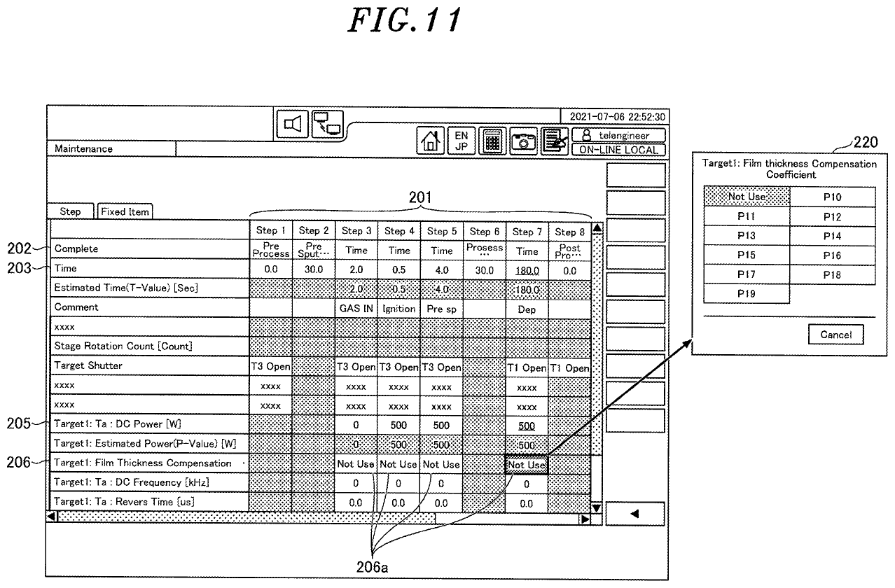

Next, the compensation device 105 obtains the adjustment coefficients a to c associated with the process module PM and the target from the adjustment coefficient storage device 104 (S12). When multiple adjustment coefficients are associated with the same process module PM and the same target, a user can select an adjustment coefficient to be used (see FIG. 11).

Next, the compensation device 105 applies the adjustment coefficient and the power consumption amount to Eq. (1) to calculate the compensation value of the input power (S13).

The recipe execution device 103 executes the recipe by compensating the input power preset in the recipe for each step of the recipe (S14). For example, when the input power to the plasma generation power source 85 before the compensation is 500 (W) and the compensation value of the input power is 10 (W), the recipe execution device 103 performs film formation by supplying the input power of 510 (W) to the plasma generation power source 85.

(Setting of Adjustment Coefficients on Recipe Screen)

FIG. 11 shows an example of a recipe screen displayed by the controller 80. In the description of FIG. 11, the differences from FIG. 9 will be mainly described. On the recipe screen of FIG. 11, the set values of the input power 205 are displayed for each step 201, and setting fields 206a of the input power compensation coefficient 206 are displayed, so that a user can select an input power compensation coefficient in units of steps.

As shown in FIG. 11, when the user clicks and scrolls down the setting field 206a, an adjustment coefficient selection screen 220 is displayed. As shown in FIG. 11, the user can select a desired adjustment coefficient from a list of multiple preset adjustment coefficients (although 10 coefficients are illustrated in FIG. 11, not all of them may have a set value).

<Main Effect>

In the present embodiment, the variation of the film thickness rate due to the increase in the used amount of the target as the progress of the film formation can be suppressed by compensating the power input to the plasma generation power source 85.

### Embodiment 3

In the present embodiment, the controller for performing “3. calculation of the compensation value of the distance between the target and the substrate support in response to the used amount of the target” will be described.

In the present embodiment, the configuration diagrams of FIGS. 1 to 4 and the functional block diagram shown in FIG. 6 described in the above embodiment are referred to.

The recipe execution device 103 of the present embodiment calculates the compensation value of the TS distance based on the power consumption amount of the plasma generation power source 85. Since the flying directions of metal atoms fly change depending on the used amount of the target, the uniformity of the film thickness may deteriorate depending on the used amount of the target (e.g., the inner circumference becomes thicker and the outer circumference becomes thinner). On the other hand, it is known that the TS distance affects the uniformity of the film thickness. In the present embodiment, it is possible to suppress the non-uniformity of the film thickness by compensating the TS distance in response to the used amount of the target. The TS distance also affects the film thickness, so that the variation of the film thickness can also be suppressed.

In the present embodiment, y in Eq. (1) indicates the compensation value of the TS distance. Since the adjustment coefficients stored in the adjustment coefficient storage device 104 may be the same as those shown in FIG. 7, the illustration thereof is omitted. The actual adjustment coefficients Na1 to Na10, Nb1 to Nb10, and Nc1 to Nc10 are values corresponding to the TS distance.

(Compensation of Input Power)

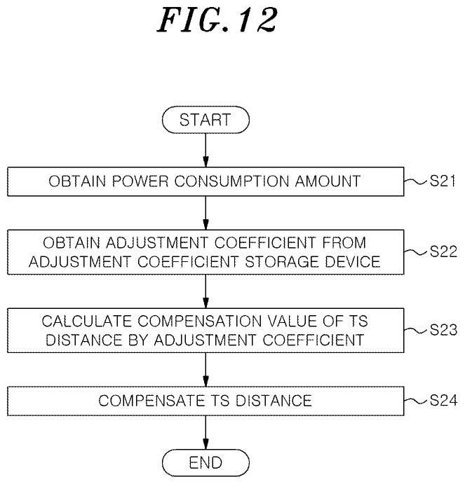

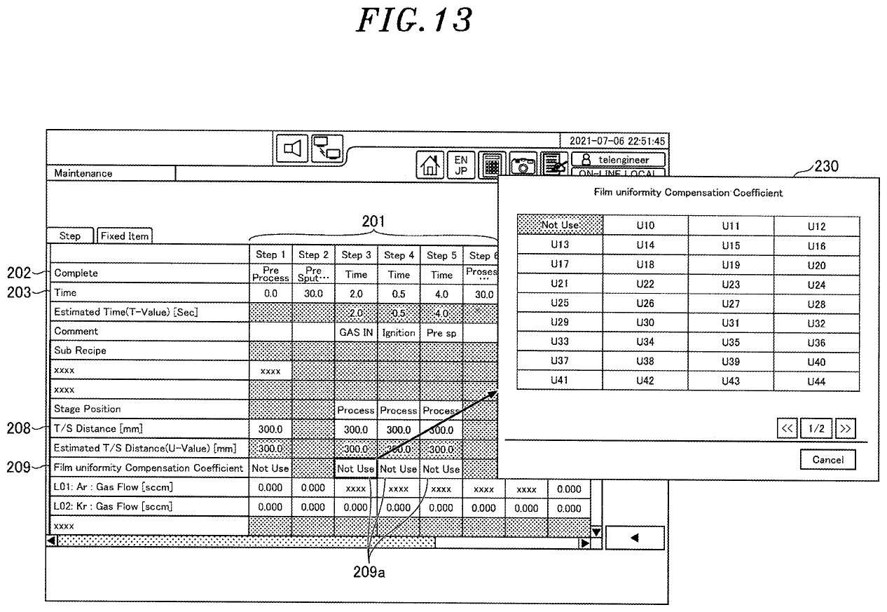

FIG. 12 is a flowchart of a condition compensation method in which the controller calculates the compensation value of the input power to the plasma generation power source 85.

First, the recipe execution device 103 obtains the power consumption amount of the plasma generation power source 85 from the monitoring device 101 (S21). The power consumption amount is a value obtained by integrating the input power to the plasma generation power source 85 from the replacement of the target.

Next, the compensation device 105 obtains the adjustment coefficients a to c associated with the process module PM and the target from the adjustment coefficient storage device 104 (S22). When a plurality of adjustment coefficients are associated with the same process module PM and the same target, a user can select an adjustment coefficient to be used (see FIG. 13).

Next, the compensation device 105 applies the adjustment coefficient and the power consumption amount to Eq. (1) to calculate the compensation value of the TS distance (S23).

The recipe execution device 103 executes the recipe after the TS distance preset in the recipe for each step of the recipe is compensated (S24). For example, when the TS distance before the compensation is 300 (mm) and the compensation value of the TS distance is 15 (mm), the recipe execution device 103 performs film formation in a state where the TS distance is 315 (mm).

(Setting of Adjustment Coefficients on Recipe Screen)

FIG. 13 shows an example of the recipe screen displayed by the controller 80. In the description of FIG. 13, the differences from FIG. 9 will be mainly described. On the recipe screen of FIG. 13, set values of a TS distance 208 are displayed for each step, and setting fields 209a of a TS distance compensation coefficient 209 are displayed, so that a user can select the TS distance compensation coefficient in units of steps.

As shown in FIG. 13, when a user clicks and scrolls down the setting field 209a, an adjustment coefficient selection screen 230 is displayed. As shown in FIG. 13, a user can select a desired adjustment coefficient from a list of multiple preset adjustment coefficients (although 35 coefficients are illustrated in FIG. 13, not all of them may have a set value).

<Main Effect>

In the present embodiment, the decrease in the uniformity of the film thickness due to the increase in the used amount of the target as the progress of the film formation can be suppressed by compensating the TS distance. Further, the effect of suppressing the variation of the film formation rate can be expected.

Although the targets in FIG. 3 are inclined at an offset angle (the targets are inclined with respect to the substrate W and shifted from the center thereof), the present disclosure can also be applied to the case where the targets are disposed in a stationary facing manner (horizontally disposed with respect to the substrate W and in the center of the substrate) or disposed in an offset stationary facing manner (horizontally disposed with respect to the substrate W and shifted from the center thereof).

### Embodiment 4

The effect obtained by combining the embodiments 1 to 3 will be described. Basically, the embodiments 1 to 3 may be combined in any combinations. In both the embodiments 1 and 2, the film thickness is compensated, so that the compensation in any one of them is valid. In the embodiment 3, the uniformity of the film thickness as well as the film thickness can be compensated, so that it is preferable to compensate both the film formation time and the TS distance by combining the embodiments 1 and 3 or to compensate both the input power and the TS distance by combining the embodiments 2 and 3.

(Other Applications)

Although the embodiments of the semiconductor manufacturing apparatus 1 have been described, the semiconductor manufacturing apparatus 1 of the present disclosure is not limited to the above embodiments, and various changes and modifications can be made within the scope of the present disclosure. The contents described in the above embodiments can be combined without contradicting each other.

For example, Eq. (1) may be a cubic or higher degree polynomial equation.

Further, the plasma generation power source 85 is not limited to the microwave plasma apparatus of the above embodiments, and may be a capacitively coupled plasma processing apparatus, an inductively coupled plasma processing apparatus, or the like.

In the present disclosure, a wafer has been described as the substrate W, but an object to be subjected to plasma processing is not limited to the wafer, and may be various substrates used for liquid crystal display (LCD), flat panel display (FPD), and the like.

The semiconductor manufacturing apparatus of the present disclosure may be applied to any type of apparatus such as an atomic layer deposition (ALD) apparatus, a capacitively coupled plasma (CCP) processing apparatus, an inductively coupled plasma (ICP) processing apparatus, an apparatus using a radial line slot antenna (RLSA), an electron cyclotron resonance plasma (ECR) processing apparatus, and a helicon wave plasma (HWP) processing apparatus.

While certain embodiments have been described, these embodiments hay′ e been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A semiconductor manufacturing apparatus for forming a film on a substrate by sputtering a target based on a recipe for performing film formation, comprising:
a storage device configured to store an adjustment coefficient for adjusting a film quality of the formed film based on the recipe;
a monitoring device configured to monitor a used amount of the target;
a compensation device configured to calculate a compensation value for compensating at least one of process conditions set in the recipe by inputting the used amount of the target monitored by the monitoring device and the adjustment coefficient into a calculation formula; and
a recipe execution device configured to execute film formation based on the recipe and the compensation value.

2. The semiconductor manufacturing apparatus of claim 1, wherein the adjustment coefficient is a coefficient of a quadratic function, and
the compensation device uses the used amount of the target as a variable of the quadratic function and calculates the compensation value using the calculation formula of the quadratic function.

3. The semiconductor manufacturing apparatus of claim 2, wherein the quadratic function is an equation for calculating a compensation value of a film formation time set in the recipe, in response to the coefficient and the used amount of the target,
the compensation device compensates the film formation time set in the recipe by calculating the compensation value of the film formation time while using the used amount of the target as a variable of the quadratic function, and
the recipe executing device executes film formation using the compensated film formation time.

4. The semiconductor manufacturing apparatus of claim 2, wherein the quadratic function is an equation for calculating a compensation value of an input power to a plasma generation power source that is set in the recipe, in response to the coefficient and the used amount of the target,
the compensation device compensates the input power of the recipe by calculating the compensation value of the input power to the plasma generation power source while using the used amount of the target as a variable of the quadratic function, and
the recipe execution device executes film formation using the compensated input power.

5. The semiconductor manufacturing apparatus of claim 2, wherein the quadratic function is an equation for calculating a compensation value of a distance between the target and a substrate support that is set in the recipe, in response to the coefficient and the used amount of the target,
the compensation device compensates the distance between the target and the substrate support in the recipe by calculating the compensation value of the distance between the target and the substrate support while using the used amount of the target as a variable of the quadratic function, and
the recipe execution device executes film formation using the compensated distance between the target and the substrate support.

6. The semiconductor manufacturing apparatus of claim 3, wherein the quadratic function is an equation for calculating a compensation value of a distance between the target and a substrate support that is set in the recipe, in response to the coefficient and the used amount of the target,
the compensation device compensates the distance between the target and the substrate support in the recipe by calculating the compensation value of the distance between the target and the substrate support while using the used amount of the target as a variable of the quadratic function, and
the recipe execution device executes film formation using the compensated distance between the target and the substrate support.

7. The semiconductor manufacturing apparatus of claim 4, wherein the quadratic function is an equation for calculating a compensation value of a distance between the target and a substrate support that is set in the recipe, in response to the coefficient and the used amount of the target,
the compensation device compensates the distance between the target and the substrate support in the recipe by calculating the compensation value of the distance between the target and the substrate support while using the used amount of the target as a variable of the quadratic function, and
the recipe execution device executes film formation using the compensated distance between the target and the substrate support.

8. The semiconductor manufacturing apparatus of claim 1, wherein the adjustment coefficient is prepared for each process module where the target is disposed.

9. The semiconductor manufacturing apparatus of claim 8, wherein the adjustment coefficient is prepared for each process module where the target is disposed and prepared for each target.

10. The semiconductor manufacturing apparatus of claim 1, wherein a list of the adjustment coefficients is displayed on a recipe screen that displays conditions of the recipe, and
the adjustment coefficient to be used for film formation is selected from the list of the adjustment coefficients.

11. The semiconductor manufacturing apparatus of claim 2, wherein a list of the adjustment coefficients is displayed on a recipe screen that displays conditions of the recipe, and
the adjustment coefficient to be used for film formation is selected from the list of the adjustment coefficients.

12. The semiconductor manufacturing apparatus of claim 3, wherein a list of the adjustment coefficients is displayed on a recipe screen that displays conditions of the recipe, and
the adjustment coefficient to be used for film formation is selected from the list of the adjustment coefficients.

13. The semiconductor manufacturing apparatus of claim 4, wherein a list of the adjustment coefficients is displayed on a recipe screen that displays conditions of the recipe, and
the adjustment coefficient to be used for film formation is selected from the list of the adjustment coefficients.

14. The semiconductor manufacturing apparatus of claim 5, wherein a list of the adjustment coefficients is displayed on a recipe screen that displays conditions of the recipe, and
the adjustment coefficient to be used for film formation is selected from the list of the adjustment coefficients.

15. A condition compensation method for a semiconductor manufacturing apparatus for forming a film by sputtering a target based on a recipe for performing film formation, comprising:
monitoring a used amount of the target;
calculating a compensation value for compensating at least one of process conditions set in the recipe by inputting the used amount of the target monitored in said monitoring and an adjustment coefficient for adjusting a film quality of the film formed based on the recipe into a calculation formula; and
executing film formation based on the recipe and the compensation value.

16. A non-transitory storage medium storing a program thereon, the program causing a controller of a semiconductor manufacturing apparatus to form a film on a substrate by sputtering a target based on a recipe for performing film formation to function as:
a storage device configured to store an adjustment coefficient for adjusting a film quality of the film formed based on the recipe;
a monitoring device configured to monitor a used amount of the target;
a compensation device configured to calculate a compensation value for compensating at least one of process conditions set in the recipe by inputting the used amount of the target monitored by the monitoring device and the adjustment coefficient into a calculation formula; and
a recipe execution device configured to execute film formation based on the recipe and the compensation value.
